(19) United States
(12) Patent Application Publication
(10) Pub. No.: US 2011/0023952 A1
(43) Pub. Date: Feb. 3, 2011

(54) PHOTOVOLTAIC CELL WITH SEMICONDUCTOR FINGERS

(75) Inventors: Brown Williams, Jamaica Plain, MA (US); Christopher E. Dubé, Lexington, MA (US)

Correspondence Address: Sunstein Kann Murphy & Timbers LLP, 125 SUMMER STREET, BOSTON, MA, 02110-1618, US

(73) Assignee: EVERGREEN SOLAR, INC., Marlborough, MA (US)

(21) Appl. No.: 12/847,046

(22) Filed: Jul. 30, 2010

Related U.S. Application Data
(60) Provisional application No. 61/229,915, filed on Jul. 30, 2009.

(51) Int. Cl. H01L 31/00; H01L 31/18

(52) U.S. Cl. 136/255; 438/57; 257/E31.001

(57) ABSTRACT

A photovoltaic cell has a semiconductor substrate formed from semiconductor material doped by a first dopant type, and a doped region over at least a portion of the substrate. The doped region is doped by a second dopant type that is opposite to that of the first dopant type to form an emitter. Moreover, the doped region is doped to a region dopant level. In addition to the substrate and emitter, the cell also has a plurality of semiconductor fingers formed on the emitter, a plurality of busbars formed from a conductor and intersecting the plurality of semiconductor fingers, and a plurality of tabs soldered to the busbars. The fingers are doped by the second dopant type to have a second dopant level, which is greater than the region dopant level.

### PRIORITY

This patent application claims priority from provisional U.S. patent application No. 61/229,915, filed Jul. 30, 2009, entitled, “PHOTOVOLTAIC CELL WITH EFFICIENT FINGER AND TAB LAYOUT COUPLED TO LIGHTLY DOPED SILICON EMITTER REGIONS,” and naming Christopher Dube and Brown Williams as inventors, the disclosure of which is incorporated herein, in its entirety, by reference.

### TECHNICAL FIELD

The invention generally relates to photovoltaic cells and modules/panels and, more particularly, the invention relates to improving photovoltaic cell efficiency.

### BACKGROUND ART

Photovoltaic cells convert light into electrical energy. To that end, a photovoltaic cell has a doped substrate that, when exposed to light, generates charge carriers, such as electrons. Conductors (typically wires, often referred to in the art as a “tabs”) coupled with the substrate conduct these electrons to another device, thus producing an electrical current.

One common photovoltaic cell technology collects the charge carriers by forming a plurality of conductive fingers on the substrate. The fingers conduct the collected charge carriers to the bonding site of one or more of the tabs, which are coupled to the substrate. These bonding sites, which are known in the art as “busbars,” provide a large surface for the tab to electrically connect with the fingers.

The fingers, which are formed from a conductor (i.e., not a semiconductor), such as silver, ohmically contact the lightly doped emitter of the underlying substrate. Specifically, the substrate has a top layer that is lightly doped in a manner that effectively forms a diode with the oppositely doped substrate. This layer typically has its highest dopant concentration at the top surface, and a decreasing concentration into the substrate until it reaches an approximately equal dopant concentration, which is generally at the junction of the diode. This top layer is the above noted emitter. Silver and other conductors, however, often do not form an efficient contact with a lightly doped emitter layer. This undesirably reduces the efficiency of the cell.

### SUMMARY OF THE INVENTION

In accordance with one embodiment of the invention, a photovoltaic cell has a semiconductor substrate formed from semiconductor material doped by a first dopant type, and a doped region on at least a portion of the substrate. The doped region is doped by a second dopant type that is opposite to that of the first dopant type to form an emitter. Moreover, the doped region is doped to a region dopant level. In addition to the substrate and emitter, the cell also has a plurality of semiconductor fingers formed on the emitter, a plurality of busbars formed from a conductor and intersecting the plurality of semiconductor fingers, and a plurality of tabs soldered to the busbars. The fingers are doped by the second dopant type to have a second dopant level, which is greater than the region dopant level.

A plurality of the busbars may be spaced between 1 and 10 millimeters apart. Various embodiments ensure that the fingers are substantially free of the conductor.

Dimensions and characteristics of the busbars and fingers can have a significant impact on performance. For example, a plurality of the fingers may have an average width of less than about 95 microns. As a second example, a plurality of the busbars can have a width of between about 100 and 500 microns, and/or be spaced between about 1 and 10 millimeters apart.

The substrate may be considered to have a front side and an opposed back side. The front side includes the emitter, busbars and fingers, while the backside may have a layer of insulator and a layer of conductive material. The layer of insulator is between the substrate and conductive material.

In accordance with another embodiment of the invention, a method of forming a photovoltaic cell adds semiconductor material to a semiconductor substrate to form a plurality of semiconductor fingers and a plurality of interface sites. The fingers and interface sites are doped by a given dopant type to have a given dopant level. The method also adds dopant material to the substrate. This additional dopant material is the given dopant type and dopes at a lower dopant level than the given dopant level. The method further adds a plurality of busbars to the plurality of interface sites, and secures tabs to at least some of the busbars. The busbars are formed from a conductor (i.e., not a semiconductor or doped semiconductor) and intersect a plurality of the fingers.

In accordance with other embodiments of the invention, a photovoltaic cell has a semiconductor substrate with an emitter having a top region doped to a first level by a given dopant type, and a plurality of semiconductor fingers generally integrated into the emitter and formed from semiconductor material. The fingers are doped by the given dopant type to have a second dopant level that is greater than the first dopant level. The cell also has a plurality of interface sites formed from semiconductor material and doped by the given dopant type to have the second dopant level, and a plurality of the busbars formed on the interface sites.

In accordance with yet another embodiment, a photovoltaic cell includes a semiconductor substrate, formed from semiconductor material, having an emitter with a layer doped by a given dopant type to a first dopant level. The cell also has a plurality of semiconductor fingers formed on the emitter layer doped by the given dopant type to have a second, greater (i.e., higher) dopant level. A plurality of the semiconductor fingers consist essentially of doped semiconductor material.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a photovoltaic panel using cells configured in accordance with illustrative embodiments of the invention.

FIG. 2 schematically shows a pair of photovoltaic cells configured in accordance with illustrative embodiments of the invention.

FIG. 3 schematically shows a bottom view of a photovoltaic cell configured in accordance with illustrative embodiments of the invention.

FIG. 4 schematically shows a top view of a photovoltaic cell configured in accordance with illustrative embodiments of the invention.

FIG. 5 schematically shows an enlarged view of fingers and busbars in the photovoltaic cell of FIG. 4.

FIG. 6 schematically shows a photovoltaic cell implementing an embodiment of the invention with discontinuous fingers.

FIG. 7 shows a process of forming a photovoltaic cell, such as those shown in FIGS. 1-5.

### DESCRIPTION OF ILLUSTRATIVE EMBODIMENTS

Rather than use fingers formed from a conductor, photovoltaic cells implementing illustrative embodiments of the invention have semiconductor fingers to conduct electrons to their local tabs and busbars. Accordingly, these fingers have no metal for conduction, thus saving the expensive step of metalizing the silicon substrate. Details of illustrative embodiments are discussed below.

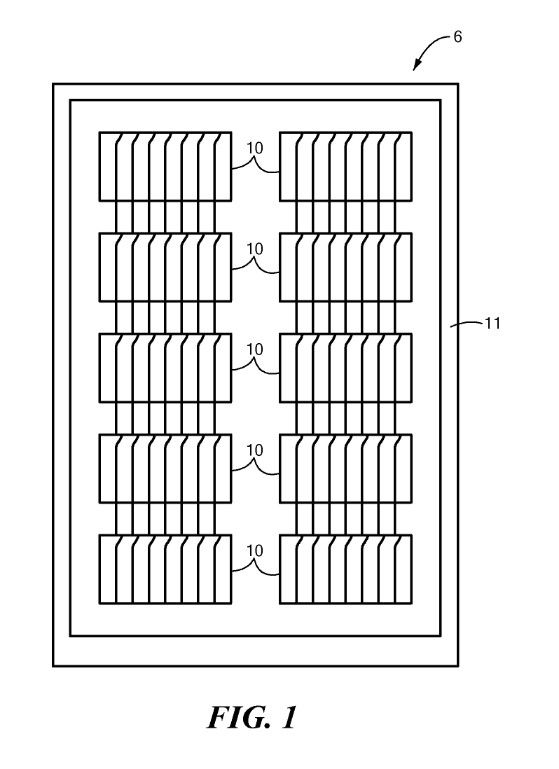

FIG. 1 schematically shows a photovoltaic module 6 (also known as a photovoltaic panel 6 or solar panel 6) that may incorporate photovoltaic cells 10 configured in accordance with illustrative embodiments of the invention. Among other things, the photovoltaic module 6 has a plurality of electrically interconnected photovoltaic cells 10 within a rigid frame 11. To protect the cells 10 and form the overall module structure, the module 6 also may have an encapsulating layer (not shown), a glass top layer (not shown), and a backskin (not shown, to provide back support). As discussed below, the individual cells 10 are electrically connected by a plurality of metal tabs 22, which FIG. 1 shows schematically only.

It should be reiterated that the module 6 shown in FIG. 1 serves merely as a schematic drawing of an actual module. Accordingly, the number of cells 10, the tab arrangement, and the cell topology can vary significantly within the context of the below description.

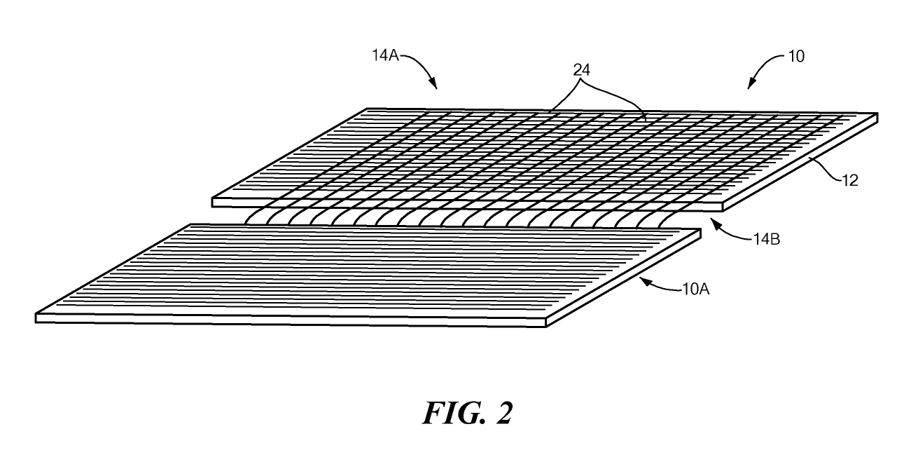

FIG. 2 schematically shows a photovoltaic cell 10 configured in accordance with illustrative embodiments of the invention and connected to a second photovoltaic cell 10A. As an example, these two cells 10 and 10A both may be within the module 6 of FIG. 1. The two cells 10 and 10A may be configured in the same manner, or in a different manner. In the example shown, the first and second photovoltaic cells 10 and 10A are serially connected to combine their power.

Among other things, the photovoltaic cell 10 has a doped substrate 12 with a semiconductor junction that forms an emitter. For example, the substrate 12 may be p-doped with a top, lightly n-doped region that forms the emitter. As known by those skilled in the art, the emitter is a lightly doped region that effectively forms an exit point for underlying charge carriers. More specifically, as known by those in the art, the emitter typically has its highest dopant concentration/level at the top surface, which diminishes until it reaches the diode between it and the region of the substrate that where the opposite carriers are the majority carriers. For example, an n-doped emitter has its highest concentration of electrons at its top surface, and that concentration diminishes until it reaches the diode. Deeper into the substrate, holes are the majority carrier. The level of dopant in the emitter thus is not necessarily uniform. The term “dopant level” or similar phrase thus can mean either the average dopant concentration of the emitter, or the maximum dopant concentration of the emitter.

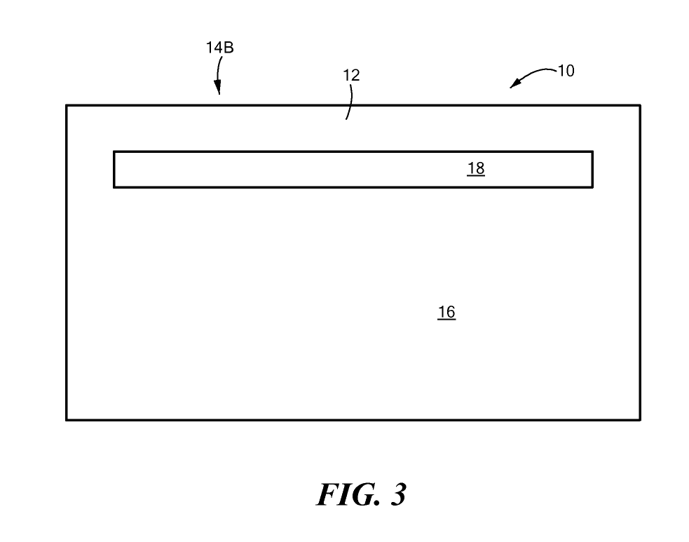

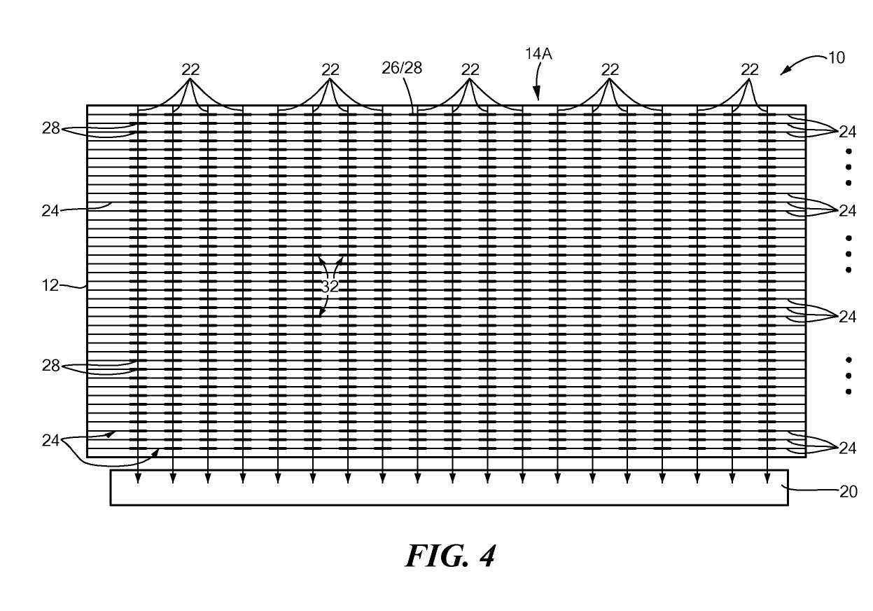

To conduct charge carriers, the top surface 14A of the substrate 12 also has a plurality of doped semiconductors and conductors (metal) on its top and bottom surfaces/surfaces 14A and 14B to collect and transmit electricity/current/electrons to an external device, such as another photovoltaic cell 10 or an external load. FIG. 3 schematically thus schematically shows a bottom view of the photovoltaic cell 10, while FIG. 4 schematically shows a top view of the same photovoltaic cell 10.

The bottom surface 14B of the substrate 12 does not receive light and thus, may be completely covered by a conductive material, such as aluminum 16, to maximize its efficiency in collecting charge carriers. This aluminum layer 16 also forms a back-surface field cell for urging electrons toward the emitter. Accordingly, as shown in FIG. 3, the bottom surface 14B of the substrate 12 has a bottom surface metallic covering 16 (e.g., aluminum) with an exposed bottom contact 18 (e.g., silver) shaped to correspond with the shape of a metallic strip 20 (discussed below with respect to FIG. 4) that electrically connects two cells 10. The photovoltaic cell 10 of FIG. 4 therefore serially connects with similar photovoltaic cells by connecting their metallic strip 20 to its bottom contact 18, and/or by connecting its metallic strip 20 to their bottom contacts 18. Alternatively, the bottom contact 18 may be embodied by one or more small pads to which the strip 24 is electrically connected.

In some embodiments, the bottom metallic covering 16 directly contacts the silicon substrate 12, thus forming the back-surface field. Alternative embodiments, however, have an insulator layer between the metallic (aluminum) layer 16 and the substrate 12. Openings through the aluminum 16 and insulator layer permit pads to ohmically contact the substrate 12. Silver paste or doped semiconductor material within those openings can form the pads.

One advantage of this latter embodiment is that it eliminates the negative effects of aluminum 16 directly contacting the silicon. Specifically, direct contact of aluminum 16 and silicon forms a low quality eutectic that causes some fraction of the charge carriers within the silicon to recombine. While eliminating that adverse result, this insulation layer undesirably does not create in the back-surface field. The inventors nevertheless believe that reducing the recombination of charge carriers can improve cell efficiency despite the fact that its metal layer 16 does not urge the charge carriers toward the emitter.

FIG. 4 shows the top surface 14A, which is textured and has an antireflective coating (not explicitly shown in the figures) to capture more incident light. In accordance with illustrative embodiments of the invention, the top surface 14A also has a pattern of deposited/integral conductor and semiconductor material to capture charge carriers and facilitate tab bonding. More specifically, the top surface 14A has a plurality of this highly doped semiconductor fingers 24 for collecting and transmitting electrons to a plurality of closely spaced metal busbars 26 and metal tabs 22. The fingers 24 in this embodiment may be considered to be integrated with the substrate 12. Alternatively, they may not be integrated with the substrate 12. Semiconductor fingers 24 directly contrast prior art designs known to the inventors, which have fingers formed from conductor material (e.g., silver). These fingers 24 have higher dopant levels than those of the emitter (e.g., higher than the emitter at the top surface of the substrate 12).

For example, many prior art designs known to the inventors deposit metal fingers directly onto the substrate 12. Therefore, in performing their function, these fingers transmit electrons received from the substrate 12 to their local busbar(s) 26. Although there may be some incidental external electron transmission, the fingers in that design provide the substantial majority of electron transmission to the busbars 26.

Those in the art have discovered, however, that conventional conductors (metals), such as silver, make a relatively poor electrical contact with the lightly doped emitter. Undesirably, this poor electrical contact produces a generally high contact resistance, which reduces cell efficiency. The art responded to this problem by increasing the dopant concentration in the region underneath the metal fingers.

For example, one relatively recent prior art design forms this more highly doped semiconductor region by selectively applying a doped silicon nanoparticle ink to the substrate 12, and then heating the substrate 12 to form this highly doped silicon/semiconductor region. Accordingly, the metal fingers formed on this highly doped semiconductor region make much better electrical contact with the substrate 12, thus improving efficiency. In other words, this additional semiconductor layer acts as an adherence or contact layer to provide a lower resistance path for the electrons in the substrate 12 to migrate into the fingers.

Many such prior art designs have very long fingers because they space their busbars relatively far apart. Contrary to conventional wisdom (due to cell coverage issues), however, the inventors have been developing photovoltaic cell designs that space their busbars 26 much closer together. For example, such a design can space the busbars 26 anywhere between 1 and 20 millimeters apart (e.g., 1-10 millimeters, 3-12 millimeters, 6-15 millimeters 6-12 millimeters, or 6-10 millimeters). The inventors realized that with appropriately doped busbars 26 spaced close together, they could eliminate the expensive step of depositing metal fingers by simply forming its fingers 24 from the doped silicon nanoparticle ink—no conductor material (metal) is necessary.

Specifically, the conductivity of the fingers, which is a function of doping, is too low to make semiconductor fingers 24 practical in prior art designs having long finger spacing between busbars. In contrast, if the busbars are spaced relatively close together, their relatively low conductivity is sufficient to appropriately conduct the majority carriers in an efficient manner; i.e., there is no need for an expensive silver or other metal finger. Instead, the inventors discovered that semiconductor fingers 24 made from a doped semiconductor material, such as a doped silicon ink previously used merely as an interface layer/site, now can provide commercially reasonable, satisfactory conduction.

For example, pairs of busbars 26, which can be continuous or discontinuous, may be considered as forming a plurality of finger segments therebetween. As noted above, the conductivity is a function of the dopant level within the semiconductor fingers 24. Accordingly, it is preferable to form the semiconductor finger segments with shorter lengths (e.g., between 1 and 10 millimeters). Larger finger lengths may suffice, but could be less efficient.

A preferred semiconductor finger 24 is formed from a doped semiconductor material that is the same as, or very similar to, that of the underlying semiconductor substrate 12. For example, a cell 10 with a polysilicon substrate 12 could have semiconductor fingers 24 formed from one or more of single crystal silicon, polysilicon, germanium, and an alloy of silicon and germanium. Indeed, as known those skilled in the art, there is a distinct difference between a conductor and a semiconductor. In particular, a conductor permits electric current to flow through it equally well in either direction. The amount of current flow depends only upon the resistance of the conductor and the amount of voltage applied across it.

In contrast, among other differences, a semiconductor permits an electric current to flow very strongly in one direction—the forward current, and very weakly in the opposite direction—the reverse current. Moreover, the amount of current flowing in each direction depends primarily upon the relatively low forward resistance and the nearly always higher reverse resistance.

To avoid confusion, it should be explicitly noted that semiconductors, such as the semiconductor fingers 24, conduct current. This does not mean, however, that a semiconductor material becomes a conductor material merely because it is doped to conduct current. Those skilled in the art understand the difference.

It also should be noted that the highly doped prior art interface layer, which provides an electrical contact for its metal fingers, may transmit a small amount of current. Such amount of current nevertheless is negligible when compared to the amount of current transmitted by the metal fingers themselves, which are substantially more conductive. Stated another way, the metal fingers perform their function by effectively acting as a short circuit for current within the semiconductor interface layer.

Semiconductor fingers 24 thus are fingers because they conduct the majority of the charge carriers to the busbars 26 (often much more than the majority of the charge carriers). Thus, a functional metal finger formed on top of what may appear to be a structure resembling a semiconductor finger 24 (e.g., the highly doped semiconductor material) effectively causes the semiconductor material simply to be an interface layer only and not a finger—it is not conducting the vast majority of current to the busbar 26.

Like prior art fingers, illustrative embodiments of the invention therefore have fingers 24 formed essentially from a single material to perform its current transmission function. In this case, that single material is a doped semiconductor material (e.g., doped silicon), while in the prior art, that single material is a conductor (e.g., silver). Illustrative embodiments of the semiconductor fingers 24 thus are free of conductive material that transmits current to the busbars 26.

In illustrative embodiments, the fingers 24 are very thin and traverse generally lengthwise (horizontally from the perspective of the figure) along the substrate 12. In a corresponding manner, the busbars 26 may include a plurality of discontinuous busbars 26 traversing generally along the width (vertically from the perspective of the figures but partly covered by tabs 22, which are discussed below) of the substrate 12. As shown and discussed below, each discontinuous busbar 26 in FIG. 4 includes a plurality of regularly spaced pads 28 along its length. In the example shown, the discontinuous busbars 26 are generally arranged in a pattern that is more or less perpendicular to the fingers 24. The busbars 26 thus intersect the fingers 24.

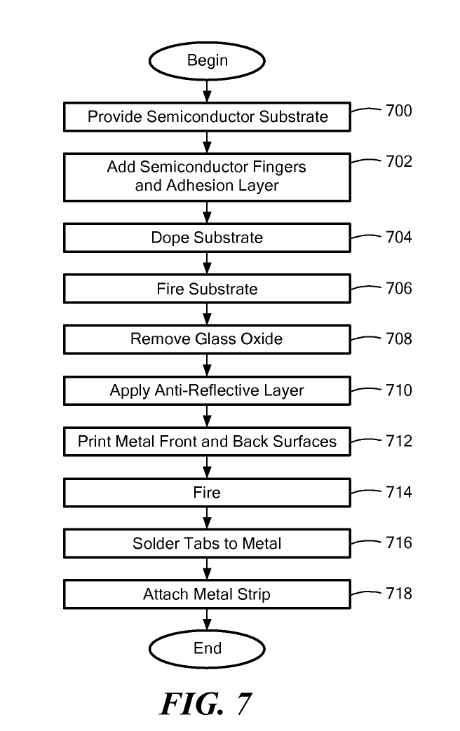

As discussed in greater detail below with respect to FIG. 7, illustrative embodiments of the invention form the busbars 26 from a conductor material, such as silver. While some embodiments may form the busbars 26 directly on the substrate 12, other embodiments may have an interface layer of highly doped silicon between the substrate 12 and one or more of its busbars 26.

As noted above, the fingers 24 are thinner than those in a typical cell. For example, some or all of the fingers 24 may have (average) thicknesses (also referred to as “widths”) that are substantially less than about 120 microns. In fact, some embodiments have finger thicknesses of less than about 60 microns (e.g., between about 40 and 60 microns, between about 60 and 95 microns, or between about 60 and 80 microns). They may have maximum height dimensions of between about 2 and tens of microns (e.g., 2-10 microns). Details of the finger thicknesses and related benefits are discussed more fully in U.S. patent application Ser. No. 12/331,586, the disclosure of which is incorporated herein, in its entirety, by reference. Other embodiments, however, do not require such thin fingers 24.

As shown in the various figures, the discontinuous busbars 26 are generally parallel to each other. In a similar manner, the horizontally oriented fingers 24 are generally parallel to each other. Alternative embodiments also may form the discontinuous busbars 26 and fingers 24 in different orientations. For example, the fingers 24, discontinuous busbars 26, or both could traverse in a random manner across the top surface 14A of the substrate 12, at an angle to the fingers 24 and discontinuous busbars 26 shown, or in some other pattern as required by the application. In addition, alternative embodiments may have two types of fingers—semiconductor fingers 24 and fingers fabricated from a conductor material, such as silver.

As noted above, the photovoltaic cell 10 also has a plurality of tab conductors 22 (referred to generally as “tabs 22” and shown in FIG. 4, among other figures) electrically and physically connected to the discontinuous busbars 26/pads 28. Among other things, the tabs 22 may be formed from silver, silver plated copper wires, or silver plated copper wires to enhance conductivity. The tabs 22 transmit electrons gathered by the fingers 24 to the above noted metallic strip 20, which is connectible to either an external load or another photovoltaic cell 10 (e.g., as shown in FIG. 1).

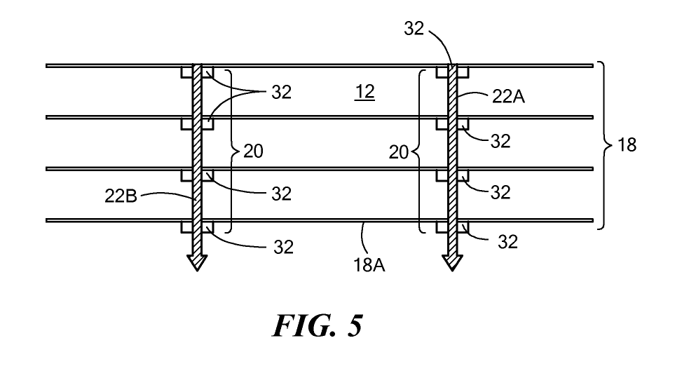

Conventional processes bond each tab 22 to a plurality of the busbar pads 28 making up a single discontinuous busbar 26. To that end, FIG. 5 schematically shows a close-up view of a specific tab 22A and its connection to the pads 28 of its discontinuous busbar 26. For example, solder may physically and electrically connect each tab 22 with its plurality of corresponding pads 28. Accordingly, only discrete portions of the tab 22 are secured to the substrate 12.

The cell 10 may have additional fingers 24 positioned beneath the tabs 22. In addition to performing the function of gathering charge carriers, these fingers 24 also beneficially aid efficiency if a tab/pad bond breaks. For more information, see co-pending U.S. patent application Ser. No. 12/511,557, the disclosure of which is incorporated herein, in its entirety, by reference.

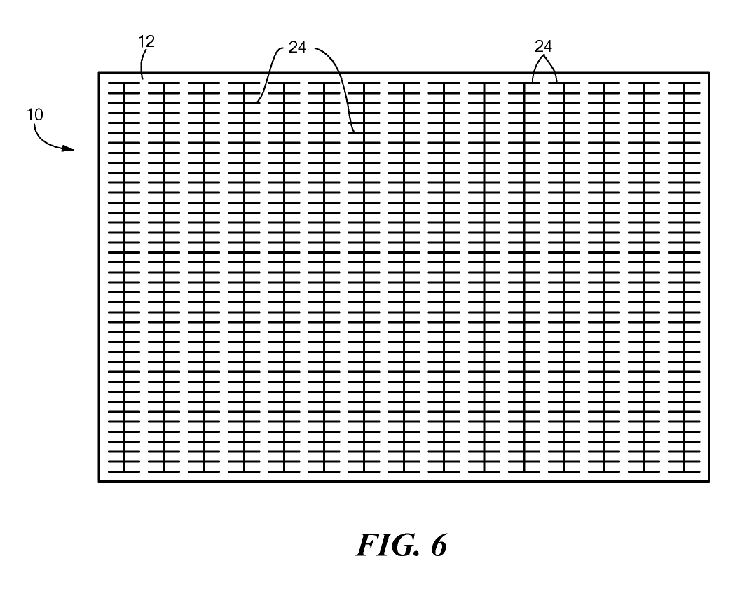

FIG. 6 shows another embodiment using discontinuous fingers 24 for collecting charge carriers (with tabs 22 removed, as in various other figures). Specifically, each (horizontal) finger 24 in this embodiment has a plurality of finger portions that each intersects a single discontinuous busbar 26. In the embodiment shown, the spacing between each finger portion of a given finger 24 (of the embodiment in FIGS. 10A and 10B) preferably is no greater than about 2 millimeters in this case. By way of example only, the spacing may be between about 0.5 and about 2 millimeters. Of course, the spacing may be less than about 0.5 millimeters or greater than 2 millimeters.

It should be reiterated that those skilled in the art can combine features of different embodiments. For example, the discontinuous fingers of FIG. 6 can be combined with continuous busbars 26 described above.

FIG. 7 shows a process of forming a photovoltaic cell 10 accordance with illustrative embodiments of the invention. It should be noted that for simplicity, this described process is a significantly simplified version of an actual process used to form a photovoltaic cell 10. Accordingly, those skilled in the art would understand that the process may have additional steps not explicitly shown in FIG. 7. Moreover, some of the steps may be performed in a different order than that shown, or at substantially the same time. Those skilled in the art should be capable of modifying the process to suit their particular requirements.

The process begins at step 700, which forms a doped substrate 12. To that end, the process may form any kind of doped substrate 12 appropriate for the intended purposes. Illustrative embodiments form a p-type doped semiconductor crystalline sheet wafer, such as a STRING RIBBON™ wafer produced by Evergreen Solar, Inc. of Marlborough, Mass. As known by those skilled in the art, this type of wafer typically is very thin, such as on the order of between about 150 and 300 microns.

After cleaning and texturing the surfaces 14A and 14B of the wafer/substrate 12, the process continues to step 702, which adds a doped semiconductor material to the top surface 14A of the substrate 12. As discussed below, this semiconductor material ultimately will form semiconductor fingers 24 and an interface layer for the busbars 26. In illustrative embodiments, the semiconductor material is an ink having heavily doped silicon and/or germanium nanoparticles. For example, the nanoparticles may be suspended in a colloidal dispersion (or colloid), such as ink, to transport and store the nanoparticles. A “colloidal dispersion” is a type of homogeneous mixture having two separate phases:

1. A continuous phase (such as a solvent), and

2. A dispersed phase (generally including individual particles were small agglomerates of particles with a diameter or outer dimension below about 100 nanometers). As an example, the semiconductor material may be similar to the nanoparticle colloidal dispersion ink disclosed in U.S. Pat. No. 7,704,866, assigned on its face to Innovalight, Inc. of Sunnyvale, Calif. The ink thus may be similar to those doped semiconductor inks distributed by Innovalight, Inc.

Illustrative embodiments screen print the semiconductor ink onto the substrate 12 in a conventional manner. The deposited ink should be doped with the same dopant type as that of the top surface 14A of the subsequently formed emitter. For example, a p-type substrate 12 should have an emitter with a top, n-type doped surface having a dopant level. This semiconductor ink thus is doped with an n-type dopant (e.g., phosphorus). As noted, the deposited ink is more highly doped than the subsequently formed, lightly doped emitter (i.e., the ink has a higher dopant level). Other techniques, such as use of inkjet technology, can deposit the semiconductor ink onto the substrate 12. Accordingly, discussion of screen printing or other specific application techniques is for exemplary purposes only.

The process continues to step 704, which diffuses a junction into the substrate 12 to form the lightly doped emitter (e.g., between about 100-200 ohms/sq). To that end, embodiments using a p-type sheet wafer may form a very thin layer of N-type material to the top surface 14A of the substrate 12. For example, this layer may have a thickness of about 0.3 microns. Among other ways, the process may apply this layer by spraying a phosphorous compound onto the top surface 14A of the wafer/substrate 12, and then heating/firing the entire substrate 12 in a furnace (step 706). While the semiconductor material may block the phosphorous from regions they cover, it is anticipated that the high dopant concentration of this semiconductor material itself provides sufficient doping to that region. Of course, the junction/emitter may be formed by other means and thus, the noted techniques are discussed for illustrative purposes only.

The firing step 706 may be performed in a single step, or at two different times. For example, in a two step firing implementation, after adding the semiconductor material to the substrate 12, the process can heat the substrate 12 to a high temperature, such as 1000 degrees C., before applying the phosphorous dopant. After applying the dopant, the process then may heat the substrate 12 to a similar or lower temperature, such as 900 degrees C., to form the emitter.

Firing undesirably produces a residual glass oxide (phosphosilicate glass) on the substrate 12. The process thus removes this glass oxide using conventional techniques, such as a glass etch (step 708). Next, the process adds the above noted electrically insulating, antireflective coating to the top surface 14A of the substrate 12 (step 710). In a manner similar to the noted texture, one primary function of the antireflective coating is to increase the amount of light coupled into the photovoltaic cell 10. The antireflective coating may be formed from conventional materials, such as silicon nitride.

Next, the process applies the metal to the front and back surfaces (step 712). Specifically, conventional screen printing processes may deposit a silver paste onto the interface sites on the top surface 14A to form a plurality of busbars 26. These busbars 26 may be continuous or discontinuous, and preferably have an underlying interface layer having a similar pattern. Since the silicon interface sites should offer sufficient contrast to the surface of the substrate 12, illustrative embodiments use a commercial screen printer vision system to deposit this top surface metal. Some embodiments, however, may extend some of the metal beyond the main surface of the busbars 26. That extended portion thus is considered part of the busbar 26, even if it extends over a portion of the thin width doped semiconductor material that otherwise would form part of a semiconductor finger.

Before, simultaneously, or after processing the top surface 14A, the process also forms metal on the bottom surface 14B. To that end, conventional screen printing processes first form the bottom contact 18 from a silver paste on the substrate 12, and then mask the bottom contact 18 to form the bottom surface metallic covering 16 (e.g., formed from aluminum). Alternatively, the process may form contacts 18 from the doped semiconductor material or silver, and then mask that contact to form the insulator layer, and the aluminum layer 16. Yet other embodiments form the back surface field substantially entirely from the doped semiconductor material, which is deposited over substantially the entire back surface of the substrate 12.

After depositing the metals on the front and back surfaces, the process continues to step 714 by firing the substrate 12 again for a very short period. The process thus passes the substrate 12 through a furnace at a high temperature for a short amount of time. For example, the process may pass the substrate 12 through a furnace at 850 degrees C. for approximately one second. This short but quick heating effectively solidifies the conductive paste forming the busbars 26, and causes the conductive paste to “fire through” the antireflective coating. In other words, the conductive paste penetrates through the antireflective coating to make ohmic contact with the substrate 12. The step also solidifies the metal on the bottom surface 14B.

The process then continues to step 716, which secures the tabs 22 to the discontinuous busbars 26. To that end, conventional processes first may screen-print solder onto each of the busbars 26, and then use a hotplate to melt the solder. At this stage, each pad 28 of a discontinuous busbar 26 has a solder ball for receiving a tab 22. A scaffolding holding a row of tabs 22 under tension thus is moved downwardly to contact each solder ball with a tab 22. The solder balls then cool, consequently securing the tabs 22 to the pads 28. One advantage of using solder balls in this process is their ability to connect securely with the tabs 22 despite irregularities in the contour of the pads 28 and substrate 12.

It should be noted that the tabs 22 electrically connect indirectly with the substrate 12 via the pads 28 only. The insulative antireflective coating/layer prevents the tabs 22 from directly electrically connecting with the substrate 12 through any other portion of the top surface 14A of the substrate 12.

The process concludes at step 718 by affixing the metal strip 24 (see FIG. 2A) to the tabs 22. Any conventional means for making this connection should suffice, such as conventional soldering techniques.

Illustrative embodiments of the invention thus provide a number of advantages over the prior art. Primarily, some of these embodiments do not require the expensive step of applying metal to the top surface 14A to form fingers. As noted, this metal typically is highly conductive silver, which is expensive. In addition, silver degrades the quality of the silicon to which it is bonded. Use of semiconductor fingers 24, however, maintains the integrity of silicon substrate 12 in those regions. Moreover, the semiconductor fingers 24 do not provide coverage to the substrate 12 as dense as a metal. Of course, this depends upon the dopant level of the semiconductor fingers 24. It is anticipated that some of the photovoltaic cell designs described above can have a one percent absolute efficiency increase when compared to prior art cell designs having metal directly bonded to the substrate 12 (without an interface layer).

Although the above discussion discloses various exemplary embodiments of the invention, it should be apparent that those skilled in the art can make various modifications that will achieve some of the advantages of the invention without departing from the true scope of the invention.

What is claimed is:

1. A photovoltaic cell comprising:
a semiconductor substrate formed from semiconductor material doped by a first dopant type;
an oppositely doped region on at least a portion of the substrate, the oppositely doped region being doped by a second dopant type that is opposite to that of the first dopant type to form an emitter, the doped region being doped to a region dopant level;
a plurality of semiconductor fingers formed on the emitter, the fingers being doped by the second dopant type to have a second dopant level, the second dopant level being greater than the region dopant level;
a plurality of busbars formed from a conductor and intersecting the plurality of semiconductor fingers; and
a plurality of tabs soldered to the busbars.

2. The photovoltaic cell as defined by claim 1 wherein a plurality of the busbars are spaced between about 1 and 10 millimeters apart.

3. The photovoltaic cell as defined by claim 1 wherein a plurality of the fingers have average width of less than about 95 microns.

4. The photovoltaic cell as defined by claim 3 wherein a plurality of the busbars have a width of between about 100 and 500 microns.

5. The photovoltaic cell as defined by claim 1 wherein the substrate has a front side and an opposed back side, the front side including the emitter, busbars and fingers, the backside having a layer of insulator and a layer of conductive material, the layer of insulator being between the substrate and conductive material.

6. The photovoltaic cell as defined by claim 1 wherein a plurality of the fingers are substantially free of the conductor.

7. A method of forming a photovoltaic cell, the method comprising:
providing a semiconductor substrate;
adding semiconductor material to the substrate to form a plurality of semiconductor fingers and a plurality of interface sites, the fingers and interface sites being doped by a given dopant type to have a given dopant level;
adding dopant material to the substrate, the dopant material being the given dopant type and doping the substrate at a lower dopant level than the given dopant level;
adding a plurality of busbars to the plurality of interface sites, the busbars being formed from a conductor and intersecting a plurality of the fingers; and
securing tabs to at least some of the busbars.

8. The method as defined by claim 7 wherein adding busbars comprises adding an array of pads to form a plurality of discontinuous busbars.

9. The method as defined by claim 8 wherein securing comprises soldering tabs to the pads.

10. The method as defined by claim 7 wherein a plurality of the tabs each has a plurality of spaced apart soldering sites along its respective busbar.

11. The method as defined by claim 7 further comprising:
heating the substrate both to form an emitter on the substrate and to integrate the fingers with the substrate.

12. A photovoltaic cell comprising:
a semiconductor substrate having an emitter with a top region doped to a first level by a given dopant type;
a plurality of semiconductor fingers generally integrated into the emitter and formed from semiconductor material, the fingers being doped by the given dopant type to have a second dopant level, the second dopant level being greater than the first dopant level;
a plurality of interface sites formed from semiconductor material and doped by the given dopant type to have the second dopant level;
a plurality of the busbars formed on the interface sites and being spaced between about 1 and 10 millimeters apart.

13. The photovoltaic cell as defined by claim 12 wherein a plurality of the fingers have an average width of less than about 95 microns.

14. The photovoltaic cell as defined by claim 12 wherein the substrate comprises polysilicon.

15. The photovoltaic cell as defined by claim 12 wherein the busbars consist essentially of a conductor, the photovoltaic cell further comprising:
a plurality of tabs soldered to the busbars.

16. The photovoltaic cell as defined by claim 15 wherein a plurality of the fingers are substantially free of the conductor.

17. The photovoltaic cell as defined by claim 15 wherein the conductor comprises silver.

18. The photovoltaic cell as defined by claim 12 wherein a plurality of the busbars are spaced less than or equal to about 10 millimeters apart

19. A photovoltaic cell comprising:
a semiconductor substrate formed from semiconductor material and having an emitter with a layer doped by a given dopant type to have a first dopant level; and
a plurality of semiconductor fingers formed on the emitter layer doped by the given dopant type, the fingers being doped by the given dopant type to have a second dopant level, the second dopant level being greater than the first dopant level,
a plurality of the semiconductor fingers consisting essentially of doped semiconductor material.

20. The photovoltaic cell as defined by claim 19 further comprising a plurality of interface sites on the emitter, and a plurality of busbars formed from a conductor on the interface sites, the interface sites being formed from semiconductor material doped by the given dopant type to the second dopant level.

21. The photovoltaic cell as defined by claim 20 wherein the fingers are free of conductor material that conducts between any of the busbars.

22. The photovoltaic cell as defined by claim 20 wherein the plurality of busbars consist essentially of the conductor.
